(19) United States
(12) Patent Application Publication
(10) Pub. No.: US 2004/0196097 A1
(43) Pub. Date: Oct. 7, 2004

(54) Am detection circuit

(76) Inventor: Hiroshi Miyagi, Niigata (JP)

Correspondence Address: DELLETT AND WALTERS, P. O. BOX 2786, PORTLAND, OR, 97208-2786, US

(21) Appl. No.: 10/484,593

(22) PCT Filed: Jun. 28, 2002
(86) PCT No.: PCT/JP02/06553

(30) Foreign Application Priority Data
Jul. 30, 2001 (JP) 2001-229647

(51) Int. Cl. H03D 1/24

(52) U.S. Cl. 329/347; 375/320

(57) ABSTRACT

An AM detection circuit which can be integrally molded with a semiconductor substrate. An AM detection circuit 17 comprises a rectification circuit 100, a carrier filtration circuit 110, and an output buffer 120. The carrier filtration circuit 110 comprises transistors 28, 29, a current source 32, and a capacitor 52. The transistors 28, 29 and the current source 32 constitute a constant current circuit of a current mirror. When the terminal voltage of the capacitor 52 decreases below the output voltage of the rectification circuit 100, the capacitor 52 is discharged by a constant current generated by this constant current circuit.

### TECHNICAL FIELD

The present invention relates to an AM detection circuit used for AM radios, television receivers, and the like.

### BACKGROUND ART

Common AM receivers employing a superheterodyne method subject an AM modulated wave signal received via an antenna to high frequency amplification and then use a frequency mixing circuit to carry out a frequency conversion. The AM receivers thus convert the signal into an intermediate frequency signal having a predetermined frequency and then execute an AM detecting process.

FIG. 3 is a diagram showing the configuration of a conventional AM detection circuit. The AM detection circuit 90 shown in FIG. 3 comprises a half-wave rectification circuit 92 and a carrier filtration circuit 94 composed of a resistor 96 and a capacitor 98. An inputted AM modulated wave signal is subjected to half-wave rectification by the half-wave rectification circuit 92. Then, carrier components are removed from the rectified signal by the carrier filtration circuit 94.

Furthermore, progress has recently been made on the research of techniques of integrally molding an analog circuit including high frequency components on a semiconductor substrate using a semiconductor process such as a MOS process. These techniques have already been put to practical use in some devices. When the semiconductor process is used to mold various circuits on one chip, the size and cost of the whole device can be reduced. Accordingly, the range of circuits molded on one chip is expected to be increased in the future.

If the components of an AM receiver including an AM detection circuit are designed to be molded on one chip using the semiconductor process, it is disadvantageously difficult to mold the whole AM detection circuit on a semiconductor substrate. This is because a capacitor 98 has a large electrostatic capacity and a resistor 96 has a large resistance value, the capacitor 98 and the resistor 96 both constituting a carrier filtration circuit 94. Thus, the half-wave rectification circuit 92 and the resistor 96 of the carrier filtration circuit 94, both shown in FIG. 3, have been molded within a one chip. The capacitor 98 is externally connected to the one-chip component as an external attachment.

### DISCLOSURE OF THE INVENTION

The present invention is created in view of this point. It is an object of the present invention to provide an AM detection circuit that can be integrally molded on a semiconductor substrate.

To accomplish this object, an AM detection circuit according to the present invention has a rectification unit that rectifies an inputted AM modulated wave signal and a carrier filtration unit that removes carrier components contained in the signal rectified by the rectification unit. Furthermore, the carrier filtration unit comprises a capacitor that is charged with an output voltage from the rectification unit and a constant current circuit that discharges the capacitor when the output voltage from the rectification unit decreases below a terminal voltage of the capacitor. A very small current generated by the constant current circuit can be used to discharge the capacitor. Consequently, even if the capacitor has a small electrostatic capacity, the terminal voltage it can be gradually reduced. Therefore, a combination of the capacitor and constant current circuit can be operated as a low pass filter to remove the carrier components contained in the AM modulated wave signal. Moreover, the capacity of the capacitor can be reduced. Thus, the whole AM detection circuit, including the carrier filtration unit, can be provided on a semiconductor substrate.

Furthermore, the above carrier filtration unit desirably further comprises an output buffer with a high input impedance which extracts the terminal voltage of the capacitor. This enables the capacitor to be discharged using only a very small current generated by the constant current circuit. Therefore, a combination of the capacitor and constant current circuit can be reliably operated as a low pass filter.

Moreover, all components including the above carrier filtration unit can desirably be integrally formed on the semiconductor substrate. As described above, a capacitor with a small electrostatic capacity can be used. Accordingly, all the components including the carrier filtration unit can be integrally molded on the semiconductor substrate. This enables a reduction in parts costs and in the number of assembly steps.

### BRIEF DESCRIPTION OF THE DRAWINGS

FIG. 1 is a diagram showing the configuration of an AM receiver according to an embodiment;

FIG. 2 is a circuit diagram showing the configuration of an AM detection circuit in detail; and

FIG. 3 is a diagram showing the configuration of a conventional AM detection circuit.

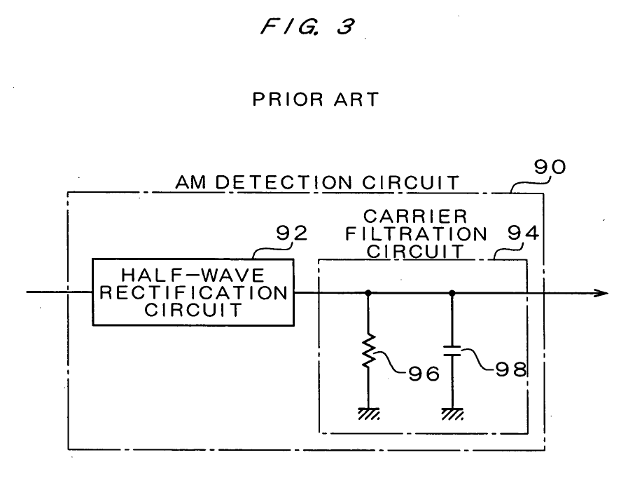

### BEST MODE FOR CARRYING OUT THE INVENTION

A detailed description will be given below of an AM receiver according to an embodiment to which the present invention is applied.

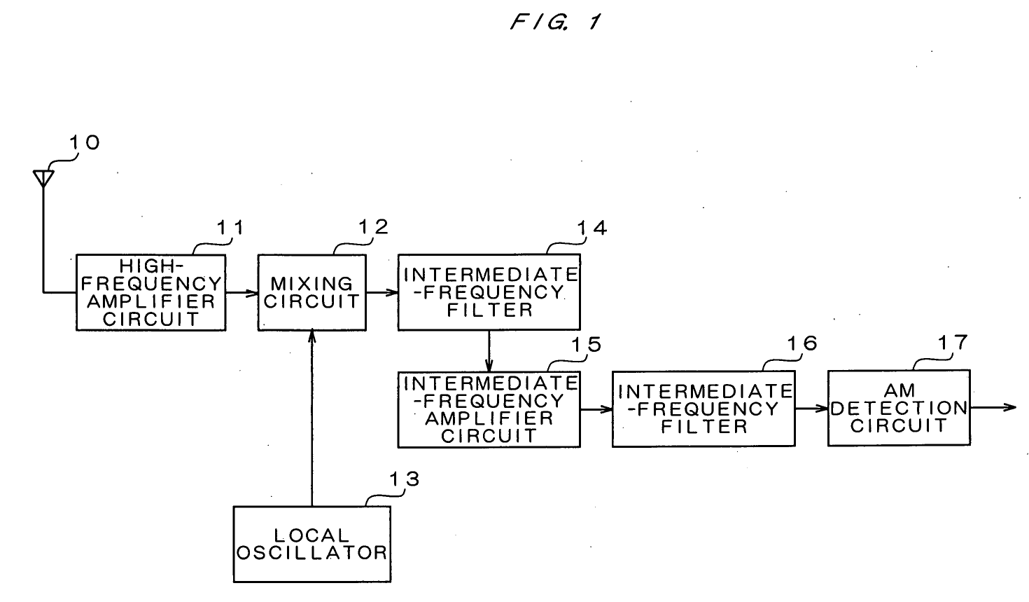

FIG. 1 is a view showing the configuration of the AM receiver according to this embodiment. As shown in FIG. 1, the AM receiver according to the present embodiment includes a high frequency amplification circuit 11, a mixing circuit 12, a local oscillator 13, intermediate frequency filters 14 and 16, an intermediate frequency amplification circuit 15, and an AM detection circuit 17. An AM modulated wave signal received by an antenna 10 is amplified by the high frequency amplification circuit 11. Then, a local oscillation signal outputted by the local oscillator 13 is mixed with the amplified signal to convert the high frequency signal into an intermediate frequency signal.

For example, the frequency of an amplified AM modulated wave signal outputted by the high-frequency amplification circuit 11 is defined as f1. The frequency of a local oscillation signal outputted by the local oscillator 13 is defined as f2. Then, an intermediate frequency signal having a frequency f1±f2 is outputted by the mixing circuit 12.

The intermediate frequency filters 14 and 16 are connected to the intermediate frequency amplification circuit 15 so as to precede and succeed the circuit 15, respectively. The intermediate frequency filters 14 and 16 extract, from the inputted intermediate frequency signal, frequency components contained in the occupied frequency bandwidth of the modulated wave signal. The intermediate frequency amplification circuit 15 amplifies the intermediate frequency signal.

The AM detection circuit 17 executes an AM detecting process on the intermediate frequency signal amplified by the intermediate frequency amplification circuit 15.

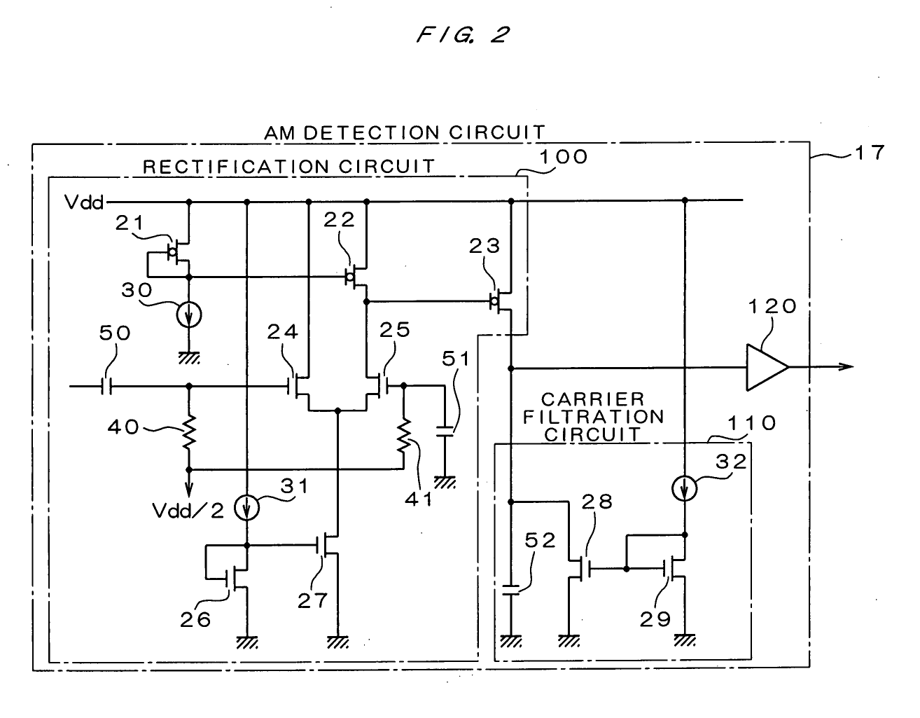

FIG. 2 is a circuit diagram showing the configuration of the AM detection circuit 17 in detail. As shown in FIG. 2, the AM detection circuit 17 according to the present embodiment comprises a rectification circuit 100, a carrier filtration circuit 110, and an output buffer 120.

The AM detection circuit 17 receives an inputted intermediate frequency signal from the preceding intermediate frequency filter 16. Then, the rectification circuit 100 subjects the intermediate frequency signal to half wave rectification. A signal outputted by the rectification circuit 100 contains carrier components. The carrier filtration circuit 110 removes the carrier components from the output signal from the rectification circuit 100. The output buffer 120 has a high input impedance. A signal generated by the carrier filtration circuit 100 is outputted to the exterior of the AM detection circuit 17 via the output buffer 120 with the high input impedance.

The rectification circuit 100 includes transistors 21 to 27, current sources 30 and 31, resistors 40 and 41, and capacitors 50 and 51. The transistors 24 and 25 perform a differential operation. Only the AC component of an AM modulated wave signal inputted to the rectification circuit 100 are inputted to a gate of one transistor 24 via the capacitor 50. A gate of the other transistor 25 is grounded in an AC manner using the capacitor 51. Furthermore, a voltage (Vdd/2) that is about half a power voltage Vdd as bias voltage is applied to the gate of each of the two transistors 24 and 25. Thus, the AC component of the AM modulated wave components is inputted only to the one transistor 24, which perform a differential amplifying operation, while the other transistor 25 is grounded in an AC manner. This causes a half-wave rectified waveform of the AM modulated wave signal to appear at a source of the transistor 22. The half-wave rectified wave form is outputted via the transistor 23, which operates as a driver.

Furthermore, the carrier filtration circuit 110 includes transistors 28 and 29, a current source 32, and a capacitor 52. The transistors 28 and 29 and the current source 32 constitute a constant current circuit of a current mirror. The constant current circuit is connected in parallel with the capacitor 52 to generate a discharge current for discharging the capacitor 52.

That is, if the voltage with the half-wave rectified waveform at the rectification circuit 100 is higher than the terminal voltage of the capacitor 52, a current flows through the transistor 23 in the rectification circuit 100 to charge the capacitor 52. On the other hand, if the voltage with the half-wave rectified waveform is lower than the terminal voltage of the capacitor 52, charges accumulated in the capacitor 52 are discharged via the transistor 28. In particular, the output buffer 120 has a high input impedance, so that the charges accumulated in the capacitor 52 do not flow toward the output buffer 120 but through the transistor 28. As described above, this discharge occurs with a constant current generated by the constant current circuit composed of the transistor 28 and others. Accordingly, by setting this current value to be smaller, the capacitor 52 can be discharged for a sufficiently long time even if it has a small electrostatic capacity.

Thus, with the carrier filtration circuit 110, included in the AM detection circuit 17 according to the present embodiment, the capacitor 52 can be discharged using a very small current generated by the constant current circuit based on a current mirror. Consequently, even if the capacitor 52 has a small electrostatic capacity, the terminal voltage of it can be gradually reduced. Therefore, a combination of the capacitor 52 and constant current circuit can be operated as a low pass filter to remove the carrier components contained in the AM modulated wave signal. Furthermore, the capacity of the capacitor 52 can be reduced, thus making it possible to mold the whole AM detection circuit 17, including the carrier filtration circuit 110, on a semiconductor substrate.

In particular, the provision of the output buffer 120 with the high input impedance enables the capacitor 52 to be discharged using only a very small current generated by the constant current circuit. Consequently, a combination of the capacitor 52 and constant current circuit can be operated reliably as a low pass filter.

The present invention is not limited to the above described embodiment. Many variations may be made to the embodiment without departing from the spirits of the present invention. For example, in the above described embodiment, the AM detection circuit 17 is molded on a semiconductor substrate. However, not only the AM detection circuit 17 but also other arrangements (the high frequency amplification circuit 11, the mixing circuit 12, and others) may be molded on the semiconductor substrate.

Industrial Applicability

As described above, according to the present invention, a very small current generated by the constant current circuit can be used to discharge the capacitor. Accordingly, even if the capacitor has a small electrostatic capacity, the terminal voltage it can be gradually reduced. Therefore, a combination of the capacitor and constant current circuit can be operated as a lowpass filter to remove the carrier components contained in an AM modulated wave signal. Furthermore, the capacity of the capacitor can be reduced, thus making it possible to mold the whole AM detection circuit, including the carrier filtration circuit, on a semiconductor substrate.

1. An AM detection circuit having a rectification unit that rectifies an inputted AM modulated wave signal and a carrier filtration unit that removes carrier components contained in the signal rectified by said rectification unit,
wherein said carrier filtration unit comprises a capacitor that is charged with an output voltage from said rectification unit and a constant current circuit that discharges said capacitor when the output voltage from said rectification unit decreases below a terminal voltage of said capacitor.

2. The AM detection circuit according to claim 1, wherein said carrier filtration unit comprises an output buffer with a high input impedance which extracts the terminal voltage of said capacitor.

3. The AM detection circuit according to claim 1, wherein all components including said carrier filtration unit are integrally molded on a semiconductor substrate.
